(19) United States
(12) Patent Application Publication
(10) Pub. No.: US 2004/0165359 A1
(43) Pub. Date: Aug. 26, 2004

(54) Docking station for a portable electronic apparatus

(75) Inventors: Chih-Chuan Cheng, Taipei City (TW); Sheng-Jou Lin, Taipei City (TW); Wei-Pin Chuang, Taipei City (TW)

Correspondence Address: BACON & THOMAS, PLLC, 625 SLATERS LANE, FOURTH FLOOR, ALEXANDRIA, VA, 22314

(73) Assignee: COMPAL ELECTRONICS, INC., Taipei City (TW)

(21) Appl. No.: 10/411,252

(22) Filed: Apr. 11, 2003

(30) Foreign Application Priority Data
Feb. 24, 2003 (TW) 92202849

(51) Int. Cl. H05K 5/00

(52) U.S. Cl. 361/730

(57) ABSTRACT

In a docking station, a connecting port unit is mounted on a housing and is coupled to an external peripheral device. A connector is mounted on the housing and is coupled electrically to the connecting port unit. The connector is coupled electrically and directly with a portable electronic apparatus so as to provide a signal transmission path between the connecting port unit and the portable electronic apparatus when the portable electronic apparatus is mounted on the housing. The circuit unit is mounted in the housing, is coupled electrically to the connector, and receives and processes an external cable television signal so as to provide an output signal associated with the cable television signal to the portable electronic apparatus via the connector.

### BACKGROUND OF THE INVENTION

1. Field of the Invention

The invention relates to a docking station, more particularly to a docking station for a portable electronic apparatus.

2. Description of the Related Art

FIG. 1 illustrates a conventional docking station 8 for a portable computer 9. The conventional docking station 8 includes a housing 80 having a top surface 82 provided with the portable computer 9 thereon, a plurality of connecting ports 81, such as a universal serial bus port, a serial port, a parallel port and a PS/2 port, and a connector 83 mounted on the top surface 82 of the housing 80 and coupled electrically to the connecting ports 81. Each connecting port 81 can be coupled electrically to an external peripheral device (not shown), such as a keyboard, a display, a printer, etc. The connector 83 couples electrically and directly with the portable computer 9 so as to provide a signal transmission path between the connecting ports 81 and the portable computer 9 when the portable computer 9 is mounted on the top surface 82 of the housing 80.

It is desirable to enhance functionality of the conventional docking station 8 to permit communication with other media platform.

### SUMMARY OF THE INVENTION

Therefore, the object of the present invention is to provide a docking station for a portable electronic apparatus that is capable of receiving and processing a cable television signal for supply to the portable electronic apparatus.

According to the present invention, there is provided a docking station for a portable electronic apparatus.

The docking station comprises:

a housing having a top surface adapted to be provided with the portable electronic apparatus thereon;

a connecting port unit mounted on the housing and adapted to be coupled to an external peripheral device;

a connector mounted on the top surface of the housing and coupled electrically to the connecting port unit, the connector being adapted to couple electrically and directly with the portable electronic apparatus so as to be able to provide a signal transmission path between the connecting port unit and the portable electronic apparatus when the portable electronic apparatus is mounted on the top surface of the housing; and

a circuit unit mounted in the housing and coupled electrically to the connector, the circuit unit being adapted to receive and process an external cable television signal so as to provide an output signal associated with the cable television signal to the portable electronic apparatus via the connector.

### BRIEF DESCRIPTION OF THE DRAWINGS

Other features and advantages of the present invention will become apparent in the following detailed description of the preferred embodiment with reference to the accompanying drawings, of which:

FIG. 1 is a perspective view of a conventional docking station for a portable electronic apparatus;

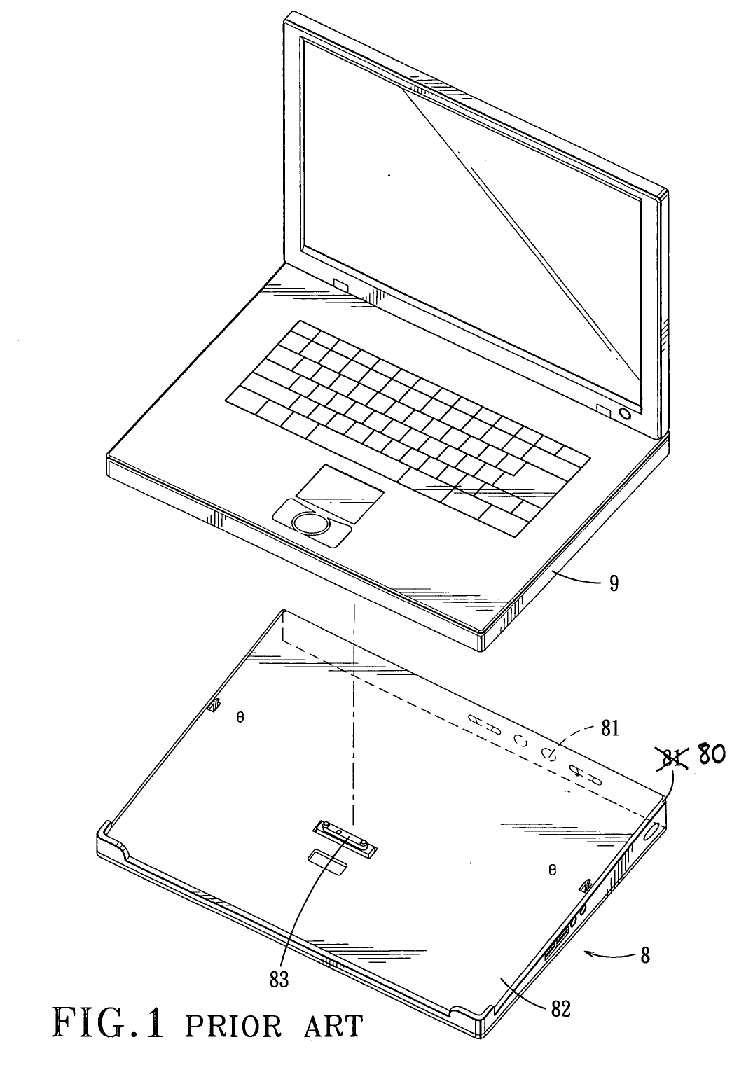

FIG. 2 is a perspective view showing the preferred embodiment of a docking station for a portable electronic apparatus according to the present invention; and

FIG. 3 is a schematic circuit block diagram of the preferred embodiment.

### DETAILED DESCRIPTION OF THE PREFERRED EMBODIMENT

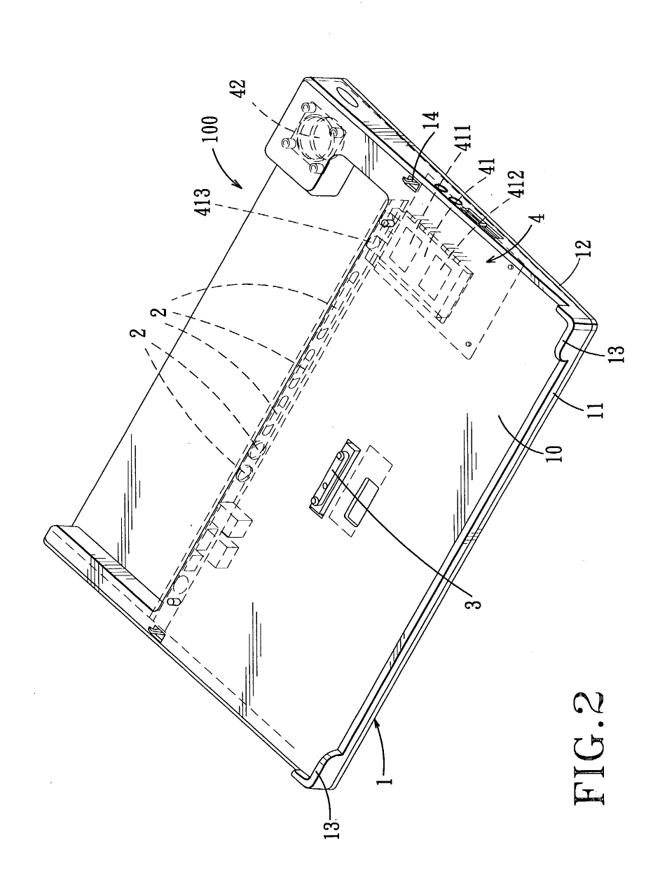

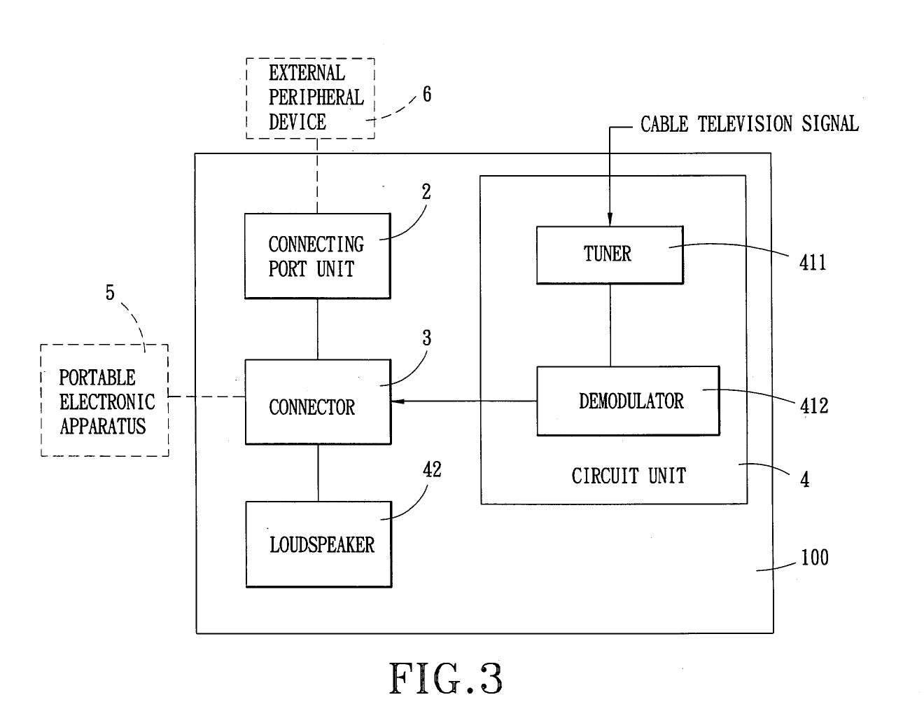

Referring to FIGS. 2 and 3, the preferred embodiment of a docking station 100 for a portable electronic apparatus 5, such as a portable computer, a personal digital assistant or a tablet computer, according to the present invention is shown to include a housing 1, a connecting port unit 2, a connector 3, and a circuit unit 4.

The housing 1, which consists of upper and lower housing bodies 11, 12 assembled to each other, has a top surface 10 adapted to be provided with the portable electronic apparatus 5 thereon. In this embodiment, the top surface 10 is formed with opposite positioning blocks 13 and opposite positioning lugs 14 to position and retain the portable electronic apparatus 5 on the top surface 10.

The connecting port unit 2 is mounted on the housing 1 and is adapted to be coupled to an external peripheral device 6, such as a printer, a scanner, a keyboard, a mouse, a display or the like. In this embodiment, the connecting port unit 2 includes a universal serial bus port, a serial port, a parallel port, PS/2 connecting port, a network connecting port and a DVI connecting port.

The connector 3 is mounted on the top surface 10 of the housing 1 and is coupled electrically to the connecting port unit 2. The connector 3 is adapted to couple electrically and directly with the portable electronic apparatus 5 so as to be able to provide a signal transmission path between the connecting port unit 2 and the portable electronic apparatus 5 when the portable electronic apparatus 5 is mounted on the top surface 10 of the housing 1.

The circuit unit 4 is mounted in the housing 1 and is coupled electrically to the connector 3. The circuit unit 4 is adapted to receive and process an external cable television signal so as to provide an output signal associated with the cable television signal to the portable electronic apparatus 5 via the connector 3. In this embodiment, the circuit unit includes a tuner 411 operable so as to receive the cable television signal, which is carried by a hybrid-fiber-coaxial cable (not shown), via a connecting port 413 that is mounted on the housing 1, that is coupled electrically to the tuner 411, and that is adapted to be coupled electrically with the hybrid-fiber-coaxial cable, and a demodulator 412 connected electrically to the tuner 411 for demodulating the cable television signal from the tuner 411 that is associated with a certain channel within a down-link frequency band so as to generate the output signal.

The docking station 100 of the preferred embodiment further includes a loudspeaker 42 mounted in the housing 1 and coupled electrically to the connector 3. Preferably, the loudspeaker 42 is a woofer for reproducing a low-frequency analog audio signal generated by a frequency-divider crossover circuit (not shown) of the portable electronic apparatus 5 such that the portable electronic apparatus 5 assembled with the docking station 100 of this invention produces a better sound output.

While the present invention has been described in connection with what is considered the most practical and preferred embodiment, it is understood that this invention is not limited to the disclosed embodiment but is intended to cover various arrangements included within the spirit and scope of the broadest interpretation so as to encompass all such modifications and equivalent arrangements.

We claim:

1. A docking station for a portable electronic apparatus, said docking station comprising:
a housing having a top surface adapted to be provided with the portable electronic apparatus thereon;
a connecting port unit mounted on said housing and adapted to be coupled to an external peripheral device;
a connector mounted on said top surface of said housing and coupled electrically to said connecting port unit, said connector being adapted to couple electrically and directly with the portable electronic apparatus so as to be able to provide a signal transmission path between said connecting port unit and the portable electronic apparatus when the portable electronic apparatus is mounted on said top surface of said housing; and
a circuit unit mounted in said housing and coupled electrically to said connector, said circuit unit being adapted to receive and process an external cable television signal so as to provide an output signal associated with the cable television signal to the portable electronic apparatus via said connector.

2. The docking station as claimed in claim 1, wherein said circuit unit includes a tuner adapted to receive the cable television signal, and a demodulator connected electrically to said tuner for demodulating the cable television signal from said tuner so as to generate the output signal.

3. The docking station as claimed in claim 1, further comprising a loudspeaker mounted in said housing and coupled electrically to said connector.

4. The docking station as claimed in claim 3, wherein said loudspeaker is a woofer.
